(19) United States
(12) Patent Application Publication
(10) Pub. No.: US 2003/0052420 A1
(43) Pub. Date: Mar. 20, 2003

(54) Semiconductor device

(75) Inventors: Hiromichi Suzuki, Tokyo (JP); Akihiko Kameoka, Iruma (JP); Masaru Yamada, Kodaira (JP); Takafumi Nishita, Iruma (JP); Fujio Ito, Hannou (JP); Junpei Kusukawa, Hitachi (JP); Ryozo Takeuchi, Hitachi (JP); Toshiaki Ishii, Oomika (JP)

Correspondence Address: Miles & Stockbridge P.C., Suite 500, 1751 Pinnacle Drive, McLean, VA, 22102-3833, US

(73) Assignee: Hitachi, Ltd.

(21) Appl. No.: 10/225,184

(22) Filed: Aug. 22, 2002

(30) Foreign Application Priority Data
Sep. 18, 2001 (JP) 2001-282651

(51) Int. Cl. H01L 23/48; H01L 23/52

(52) U.S. Cl. 257/787; 257/796; 257/690; 257/692

(57) ABSTRACT

Described is a semiconductor device comprising a plurality of inner leads each made of copper or an alloy thereof; a heat sink made of copper or an alloy thereof, bonded to one end of each of a plurality of inner leads via an insulating adhesive layer and having a semiconductor element mounted on the heat sink via a metal wire; a plurality of metal wires each electrically connecting the semiconductor element and each of the plurality of inner leads; an encapsulating resin encapsulating the semiconductor element and the plurality of metal wires; and a plurality of outer leads protruded outside of the encapsulating resin and bent in the gullwing form. The encapsulating resin has been added with an additive forming a compound with an ionic impurity so that water at the peeling portion becomes near neutral, which prevents reaction and easy elution of copper, thereby preventing Cu migration.

### BACKGROUND OF THE INVENTION

The present invention relates to a semiconductor device, particularly to a resin-encapsulated semiconductor device.

In recent years, with ever-increasing integration and function in semiconductor devices, the heat generation amount of a semiconductor element is on the rise. In order to release the heat generated from the semiconductor element, copper or a copper alloy (containing a trace amount of Ag, Sn, Fe, Cr, Zn, Ni, Mg, P, or Si to improve strength) excellent in heat conductivity is now employed instead of 42 alloy (42% Ni—Fe alloy) conventionally employed as a material of a lead frame.

Since microcomputers dissipate much heat, efficient heat release is inevitable for them. For this purpose, known is HQFP (quad flat package with heat sink), that is, a package using a lead frame equipped with a heat sink. In this package, the heat sink and the lead frame are joined by an adhesive layer.

FIG. 29 is an overall plan view of the conventional HQFP in Comparative Example, FIG. 30 illustrates one structure example of the HQFP in Comparative Example; and FIG. 31 is a plan view illustrating the inside of the HQFP in Comparative Example. The HQFP is usually fabricated in the below-described manner.

Upon fabrication of HQFP 100 as shown in FIGS. 29 to 31, a heat sink 3 having thereon an adhesive layer 2 formed by the application of a polyimide resin is first bonded to an inner lead 1a portion of a lead frame 1, followed by thermal contact bonding, curing and fixing. A semiconductor element (semiconductor chip) 4 is then adhered onto the heat sink or a die pad of the lead frame 1 by an adhesive member 5 such as silver (Ag) paste.

Between the electrode on the semiconductor element and the tip of the inner lead is connected via a metal wire 6. In most cases, silver (Ag) plating 7 for connection of a metal wire or the like is applied in advance to at least a portion of the inner lead 1a to be connected to the metal wire 6 in order to secure their connection.

The semiconductor element 4, metal wire 6, inner lead 1a and a portion or whole of the heat sink 3 are then encapsulated with an encapsulating resin 8 such as epoxy resin. In the end, the outer lead 1b portion of the lead frame 1 is plated and then bent to form an outer lead 1b. The fabrication step ends with marking.

### SUMMARY OF THE INVENTION

It is the common practice to carry out various reliability test on semiconductor devices before they are put on the market. PCT (pressure cooker test) as accelerated test of moisture resistance is one of these tests. The HQFP of the conventional structure is however accompanied with the problem that deterioration phenomena such as leakage and short circuit occur from about 200 hours after the test is started.

As a result of analysis, the present inventors have found that these deterioration phenomena upon PCT owe to the following reasons.

FIGS. 32 and 33 are cross-sectional views of the HQFP in Comparative Example (conventional structure), taken along a line I-I of FIG. 30, The above-descried problem will next be described specifically based on these FIGS. 32 and 33. FIG. 32 is a cross-sectional view before PCT, while FIG. 33 is that after PCT. To a lead frame 1, a heat sink 3 is joined via an adhesive layer 2 and these members are all encapsulated with an encapsulating resin 8.

In HQFP 100, as illustrated in FIG. 32, no film has been formed, for example, by plating on a portion of an inner lead 1a to be bonded to the adhesive layer 2. In other words, copper or a copper alloy which is the material of the inner lead 1a is exposed.

The above-described PCT is conducted at a temperature as high as 121° C. Owing to a difference in a coefficient of thermal expansion among materials, described specifically, that of the encapsulating resin 8 being 10 to 30 ppm/° C., that of copper or a copper alloy of the lead frame 1 and heat sink 3 being about 17 ppm/° C. for and that of the adhesive layer 2 being 30 to 40 ppm/° C., peeling portion 9 appears along each of the interface between the lead frame 1 and the adhesive layer 2, and the interface between the encapsulating resin 8 and the adhesive layer 2. Occurrence of peeling is a first problem.

The PCT is conducted under such severe conditions as 121° C./100% RH/2 atm, so that when the peeling portion 9 appears along each of the interface between the lead frame 1 and the adhesive layer 2 and that between the encapsulating resin 8 and the adhesive layer 2, water penetrating into the semiconductor device through the interface between the lead frame 1 and the adhesive layer 2 or the encapsulating resin 8 itself stays inside of the peeling portion 9.

Water thus pooled in the peeling portion 9 tends to show acidity, influenced by the components extracted from the encapsulating resin 8, adhesive layer 2, and adhesive member 5 (paste material or the like). The components thus extracted are, for example, an organic acid contained in the encapsulating resin 8, chlorine ion or component acidifying the extract.

This acid solution dissolves therein copper or a copper alloy which is the material of lead frame 1 and ionizes it. It is then re-deposited as deposited copper 10, causing a short-circuit between leads. This phenomenon (ion migration) is a second problem.

When, at a portion of the tip of the inner lead 1a to which silver plating 7 or the like has been applied to connect the tip of the inner lead with the metal wire 6, the plating 7 metal and copper or copper alloy used as a material for the lead frame 1 are simultaneously exposed to water, bonding of different metals leads to the formation of a cell, which accelerates the above-described phenomenon further.

FIGS. 34 and 35 illustrate the end peripheral portion (Portion J) of the heat sink 3 of HQFP 100 in Comparative Example (conventional structure) of FIG. 30. FIG. 34 is Portion J before PCT, while FIG. 35 that after PCT. The lead frame 1 and the heat sink 3 are joined via the adhesive layer 2 and they are all encapsulated with the encapsulating resin 8.

As illustrated in FIG. 34, no film is formed, for example, by plating at the end portion 3a of the heat sink and copper or a copper alloy which is a material of the heat sink 3 is exposed.

Also at the end portion 3a of the heat sink, peeling portion 9 appears after PCT as illustrated in FIG. 35 and water is accumulated in the peeling portion 9. The acidic water thus accumulated dissolves therein copper or copper alloy, which is the material of the heat sink, and ionizes it. The resulting ion is then re-deposited as a deposited copper 10, causing a short-circuit phenomenon between the lead frame 1 and heat sink 3.

As a countermeasure against ion migration, proposed in Japanese Patent Laid-Open No. Hei 10(1998)-163410 is a method for preventing ion migration in taped lead frame, which comprises forming a protective film at a portion of a lead to be contacted with the adhesive.

However, this proposal is made to prevent diffusion and movement of copper within an adhesive of the taped lead frame which will otherwise occur by energization on an electric field, and is different in a device structure or ion migration phenomenon from the lead frame equipped with a heat sink and the semiconductor device using it which are taken up herein.

In the above-described patent, the ion migration of copper within the adhesive is overcome by changing the material of the adhesive, more specifically, using a maleimide or polyimide adhesive instead of phenolic resin adhesive.

In Japanese Patent Laid-Open No. Hei 8(1996)-204098, proposed is a lead frame equipped with a heat sink wherein, in order to prevent electric short-circuit between the lead frame and the end portion of the heat sink which will otherwise occur owing to the flash remaining after the heat sink is punched out, an insulating film is formed on a surface of a lead frame to be joined with the adhesive layer in such a way that the insulating film will protrude from the end portion of the heat sink.

By this method, occurrence of migration between leads or between lead and heat sink, which is the problem of the present invention, cannot be prevented when peeling occurs.

Particularly, no description of migration between leads is included in the above-described patent.

The technique in Japanese Patent Laid-Open No. 8(1996)-204098 described as a countermeasure against migration is therefore insufficient, for example, for treating a narrow-pitch type semiconductor device having leads disposed with narrow spacing.

An object of the present invention is therefore to provide a semiconductor device reduced in peelings or cracks and if any, free from inconveniences such as leakage or short-circuit due to ion migration.

The above-described and other objects, and novel features of the present invention will become apparent from the following description of the present specification and the accompanying drawings.

Of the inventions disclosed by the present application, typical ones will next be summarized briefly.

In one aspect of the present invention, there is thus provided a semiconductor device comprising a plurality of leads each made of copper or an alloy thereof, a semiconductor element, a plurality of metal wires connecting the semiconductor element with each of the plurality of leads, and an encapsulating resin encapsulating therewith the semiconductor element, the plurality of leads and the plurality of metal wires, wherein the encapsulating resin has been added with an additive forming a compound with an ionic impurity.

In another aspect of the present invention, there is also provided a semiconductor device as described above, wherein the encapsulating resin has been added with an additive for controlling the pH of a resin extract available upon the pressure cooker test to 5.5 or greater but not greater than 10.

### BRIEF DESCRIPTION OF THE DRAWINGS

FIG. 1 is a plan view illustrating the structure of HQFP which is one example of a semiconductor device according to Embodiment 1 of the present invention;

FIG. 2 is a cross-sectional view illustrating the structure of HQFP in FIG. 1;

FIG. 3 is a plan view illustrating the inside structure of the HQFP in FIG. 1;

FIG. 4 is an enlarged fragmentary cross-sectional view illustrating the structure taken along a line A-A in FIG. 2;

FIG. 5 is an enlarged fragmentary cross-sectional view illustrating the structure of Portion B in FIG. 2;

FIG. 6 is a graph of a change in an elution amount showing one example of the relationship between the pH of a resin extract and the elution amount of copper in the semiconductor device according to Embodiment 1 of the present invention;

FIG. 7 is a graph of a pH change showing one example of the relationship between the concentration of an additive and pH of the resin extract in the semiconductor device according to Embodiment 1 of the present invention;

FIG. 8 is a graph of a change in an electroconductivity showing one example of the relationship between the concentration of the additive and the electroconductivity of the resin extract in the semiconductor device according to Embodiment 1 of the present invention;

FIG. 9 is a cross-sectional view illustrating the structure of BGA which is one example of a semiconductor device according to Embodiment 2 of the present invention;

FIG. 10 is a cross-sectional view illustrating the package structure of the BGA of FIG. 9;

FIG. 11 is a plan view illustrating the inside structure of the BGA of FIG. 9;

FIG. 12 is a cross-sectional view illustrating the cross-section taken along a line E-E of FIG. 11;

FIG. 13 is an enlarged fragmentary cross-sectional view illustrating the structure of Portion F of FIG. 12;

FIG. 14 is a cross-sectional view illustrating the structure of another BGA, which is one example of the semiconductor device according to Embodiment 2 of the present invention;

FIG. 15 is a cross-sectional view illustrating the structure of MCM which is one example of a semiconductor device according to Embodiment 3 of the present invention;

FIG. 16 is an enlarged fragmentary cross-sectional view illustrating the cross-sectional structure taken along a line G-G of FIG. 15;

FIG. 17 is an enlarged fragmentary cross-sectional view illustrating the structure of Portion H of FIG. 15;

FIG. 18 is an enlarged fragmentary cross-sectional view illustrating the structure of HQFP which is one example of a semiconductor device according to Embodiment 4 of the present invention;

FIG. 19 is an enlarged fragmentary cross-sectional view illustrating the structure of HQFP which is one example of a semiconductor device according to Embodiment 5 of the present invention;

FIG. 20 is an enlarged fragmentary cross-sectional view illustrating the structure of HQFP which is one example of a semiconductor device according to Embodiment 6 of the present invention;

FIG. 21 is an enlarged fragmentary cross-sectional view illustrating the structure of HQFP which is one example of a semiconductor device according to Embodiment 7 of the present invention;

FIG. 22 is an enlarged fragmentary cross-sectional view illustrating the structure of HQFP which is one example of a semiconductor device according to Embodiment 8 of the present invention;

FIG. 23 is an enlarged fragmentary cross-sectional view illustrating the structure of HQFP which is one example of a semiconductor device according to Embodiment 17 of the present invention;

FIG. 24 is a plan view illustrating the structure of HQFP which is one example of the semiconductor device according to Embodiment 4 of the present invention;

FIG. 25 is a cross-sectional view illustrating the structure of the HQFP of FIG. 24;

FIG. 26 is a plan view illustrating the inside structure of the HQFP of FIG. 24;

FIG. 27 is an enlarged fragmentary cross-sectional view illustrating the structure of Portion D in FIG. 25;

FIG. 28 is an enlarged fragmentary cross-sectional view illustrating one example of the semiconductor device (HQFP) of the present invention which has a lead plated, on the whole surface thereof, with Pd and is packaged by Pb-free (lead) soldering;

FIG. 29 is a plan view illustrating the structure of the semiconductor device (HQFP) in Comparative Example;

FIG. 30 is a cross-sectional view illustrating the structure of the HQFP of FIG. 29;

FIG. 31 is a plan view illustrating the inside structure of the HQFP of FIG. 29;

FIG. 32 is an enlarged fragmentary cross-sectional view illustrating the cross-sectional structure taken along a line I-I of FIG. 30;

FIG. 33 is an enlarged fragmentary cross-sectional view illustrating the cross-sectional structure of FIG. 32 after PCT;

FIG. 34 is an enlarged fragmentary cross-sectional view illustrating the end peripheral portion (Portion J) of the heat sink of FIG. 30;

FIG. 35 is an enlarged fragmentary cross-sectional view illustrating the cross-sectional structure of FIG. 34 after PCT; and

FIG. 36 shows evaluation results, by a pressure cooker test, of moisture resistance of the semiconductor devices (HQFPs) of the present invention upon covering a lead with a metal or resin without adding an additive to an encapsulating resin.

### DETAILED DESCRIPTION OF THE PREFERRED EMBODIMENTS

Embodiments of the present invention will hereinafter be described in detail with reference to the accompanying drawings. Throughout the drawings for describing these embodiments, like reference characters designate like or corresponding parts, and their descriptions are omitted where they are repetitive. Description of the same or similar part is not repeated in principle unless it is particularly necessary.

Furthermore, while when it is necessary on convenience, the following embodiments are described as divided into plural sections or embodiments. Unless otherwise clearly indicated, they are not independent each other, but one is in a relationship of a modification example, a detail or an additional description of a part or the whole of the other.

In the following embodiments, in the case where a number of an element (including numbers, numerical values, amounts and ranges) is referred, it is not limited to the particular value, but it may be more than or less than the particular value, except the case where it is clearly indicated or it is theoretically clear that it is limited the particular value.

Furthermore, in the following embodiments, it is not needless to say that a constitutional element (including an elemental step) is not always necessary except the case where it is clearly indicated or it is theoretically clear that it is necessary.

Similarly, in the following embodiments, in the case where a shape or a positional relationship of a constitutional element is referred, it substantially includes those approximate or similar to it except the case where it is clearly indicated or it is theoretically clear that it is not included. This also applies to the numerical value and range.

(Embodiment 1)

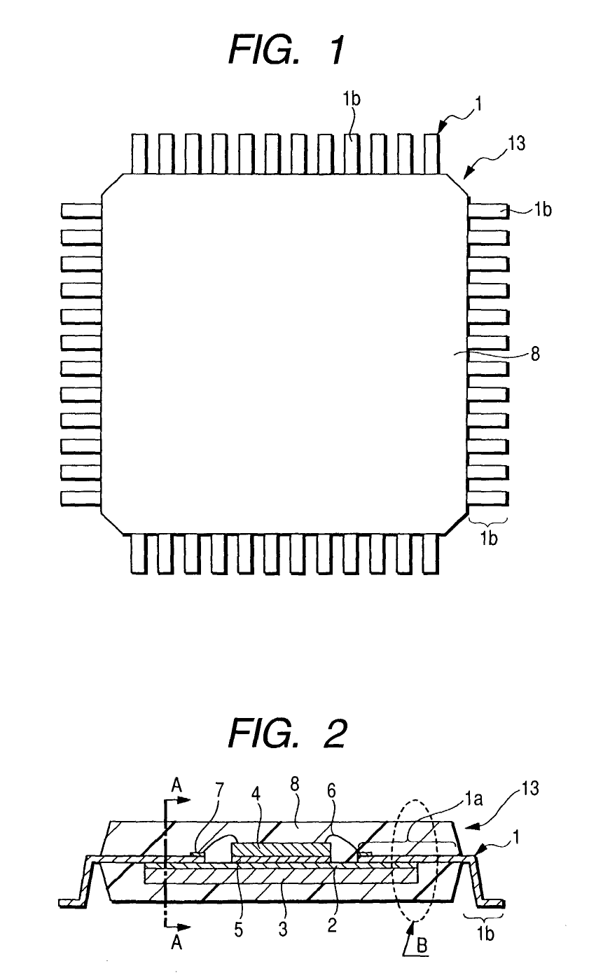

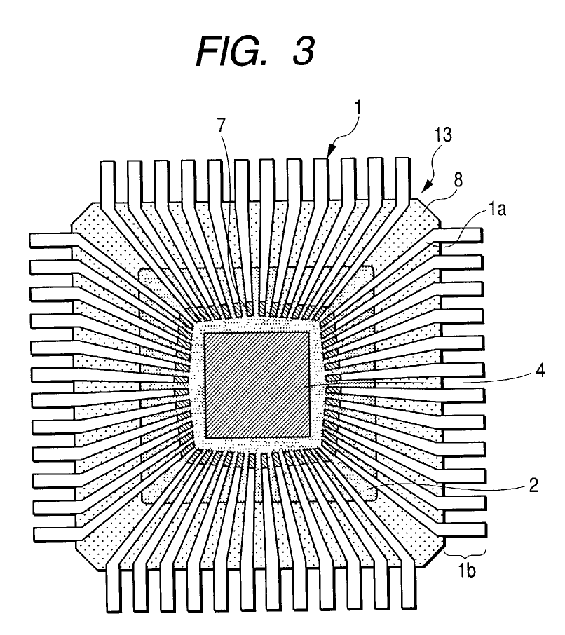

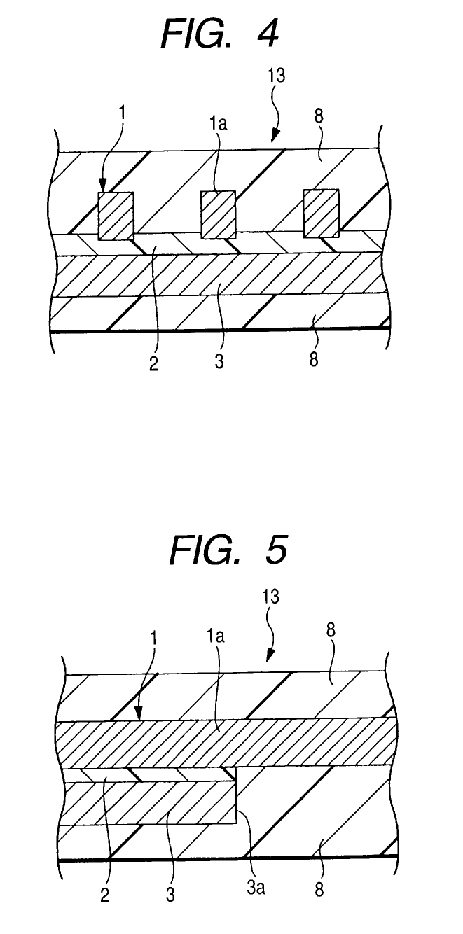

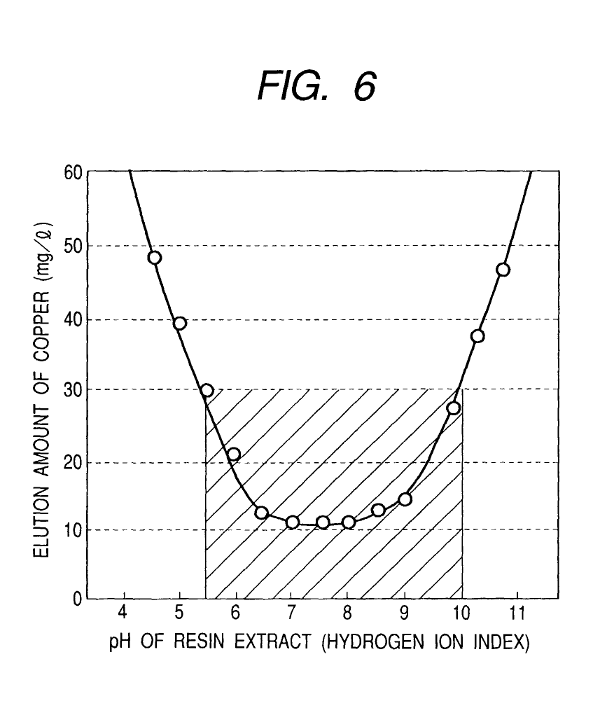

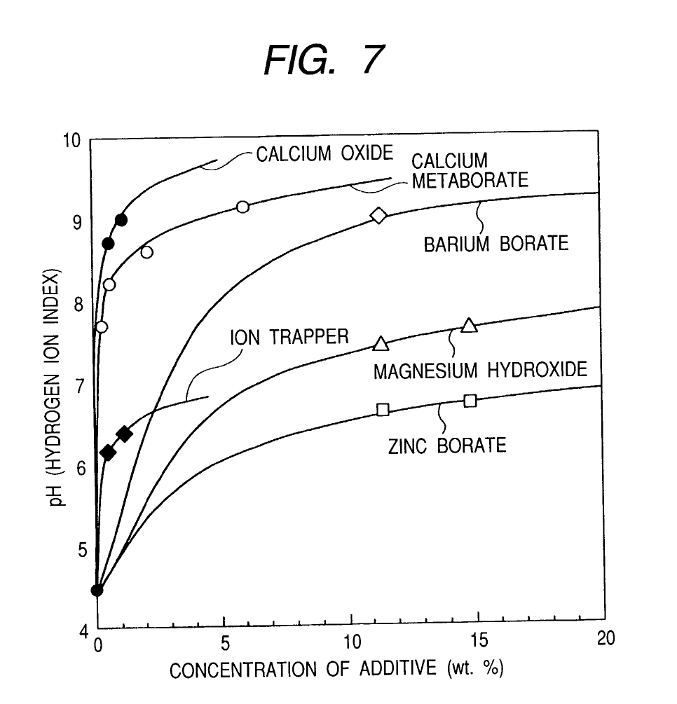

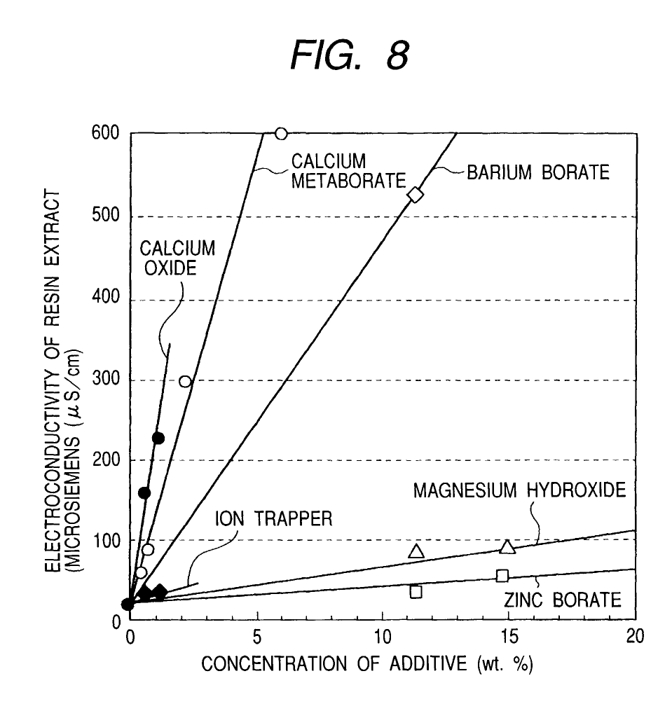

FIG. 1 is a plan view illustrating the structure of HQFP which is one example of a semiconductor device according to Embodiment 1 of the present invention; FIG. 2 is a cross-sectional view illustrating the structure of the HQFP in FIG. 1; FIG. 3 is a plan view illustrating the inside structure of the HQFP in FIG. 1; FIG. 4 is an enlarged fragmentary cross-sectional view illustrating the cross-sectional structure taken along line A-A in FIG. 2; FIG. 5 is an enlarged fragmentary cross-sectional view illustrating the structure of Portion B in FIG. 2; FIG. 6 is a graph of a change in an elution amount showing one example of the relationship between the pH of a resin extract and the elution amount of copper in the semiconductor device according to Embodiment 1 of the present invention; FIG. 7 is a graph of a pH change showing one example of the relationship between the concentration of an additive and pH of the resin extract in the semiconductor device according to Embodiment 1 of the present invention; and FIG. 8 is a graph of a change in an electroconductivity showing one example of the relationship between the concentration of the additive and the electroconductivity of the resin extract in the semiconductor device according to Embodiment 1 of the present invention.

The semiconductor device of FIG. 1 or 2 according to Embodiment 1 is a resin-encapsulated type and at the same time, a high heat dissipation type equipped with a heat sink 3. As one example of such a device, HQFP 13 will be described in this Embodiment 1.

HQFP 13 has a semiconductor element 4 which is a semiconductor chip having a semiconductor integrated circuit formed thereon; a plurality of inner leads 1a each made of copper or an alloy thereof and extending around the periphery of the semiconductor element 4; a heat sink 3 which is made of copper or an alloy thereof, is bonded to one end (end portion on the chip side) of the plurality of inner leads 1a via an insulating adhesive layer 2 and having thereon the semiconductor element 4 via the adhesive layer 2; a plurality of metal wires 6 electrically connecting the semiconductor element 4 and each of the plurality of inner leads 1a; an encapsulating resin 8 encapsulating therewith the semiconductor element 4, the plurality of metal wires 6 and the heat sink 3; and a plurality of outer leads 1b formed integral with each of the inner leads 1a, protruded out of the encapsulating resin 8 and bent in the gullwing form. The encapsulating resin 8 has been added with an additive which forms a compound with an ionic impurity.

In the HQFP 13, the encapsulating resin 8 contains an additive which forms a compound with an ionic impurity so that when moisture resistance acceleration test is conducted, an ionic impurity contained in the encapsulating resin 8 or another ion impurity which has entered from the outside of the HQFP 13 through the encapsulating resin 8 forms a compound with the additive in the encapsulating resin 8, thereby preventing the ionic impurity from being extracted.

This makes it possible to suppress the reaction of copper (Cu) of the inner lead 1 or heat sink 3, thereby preventing deposition of copper and, in turn, short-circuit due to Cu migration (ion migration).

As illustrated in FIG. 2, the semiconductor element 4 is fixed onto the adhesive layer 2 by an adhesive member 5 such as Ag paste.

In other words, the semiconductor element 4 is fixed onto the adhesive layer 2, which has been applied to the heat sink 3, via the adhesive member 5 and as illustrated in FIGS. 3 to 5, the end portion of each of the inner leads 1a on the chip side (element side) is bonded to the adhesive layer 2.

The adhesive layer 2 is, for example, a polyimide resin. Since the encapsulating resin 8 is, for example, an epoxy resin, the adhesive layer 2 is greater in coefficient of thermal expansion than the encapsulating resin 8.

The adhesion force between the heat sink 3 and the adhesive layer 2 applied onto the heat sink 3 is very high. Between the encapsulating resin 8 and the heat sink 3 made of copper or an alloy thereof, there exists a large difference in the coefficient of thermal expansion.

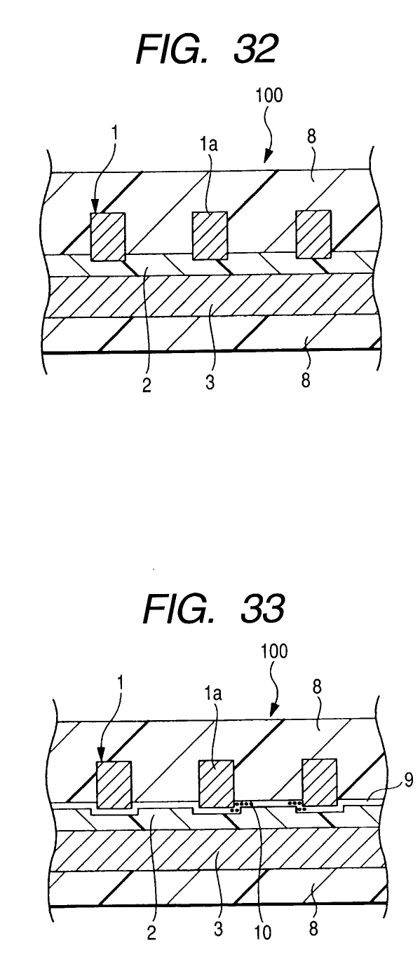

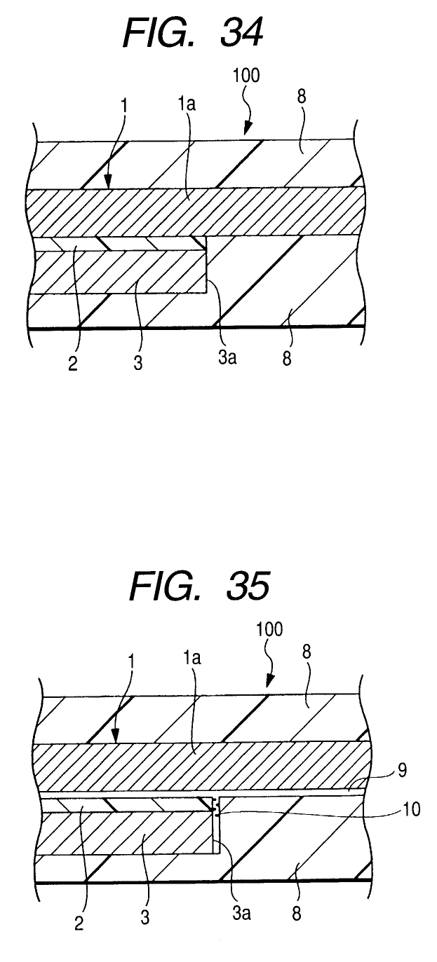

Accordingly, water tends to gather along the interface between the adhesive layer 2 and the encapsulating resin 8 or the interface between the adhesive layer 2 and the inner lead 1a as illustrated in Comparative Example of FIG. 32, or the interface between the end portion 3a of the heat sink and the encapsulating resin 8 as illustrated in Comparative Example of FIG. 34, which causes peeling at such an interface of weak bonding.

In such a structure having interfaces which are apt to cause peeling, the HQFP 13 of Embodiment 1 is capable of interfering with deposition of copper on the above-described interfaces, thereby preventing generation of Cu migration.

Each of the inner leads 1a has, at a portion thereof to be connected with the metal wire 6, Ag plating 7 for this purpose, whereby the connection strength with the gold (Au) metal wire 6 is heightened.

Next, the conditions of the additive to be added to the encapsulating resin 8 will be described.

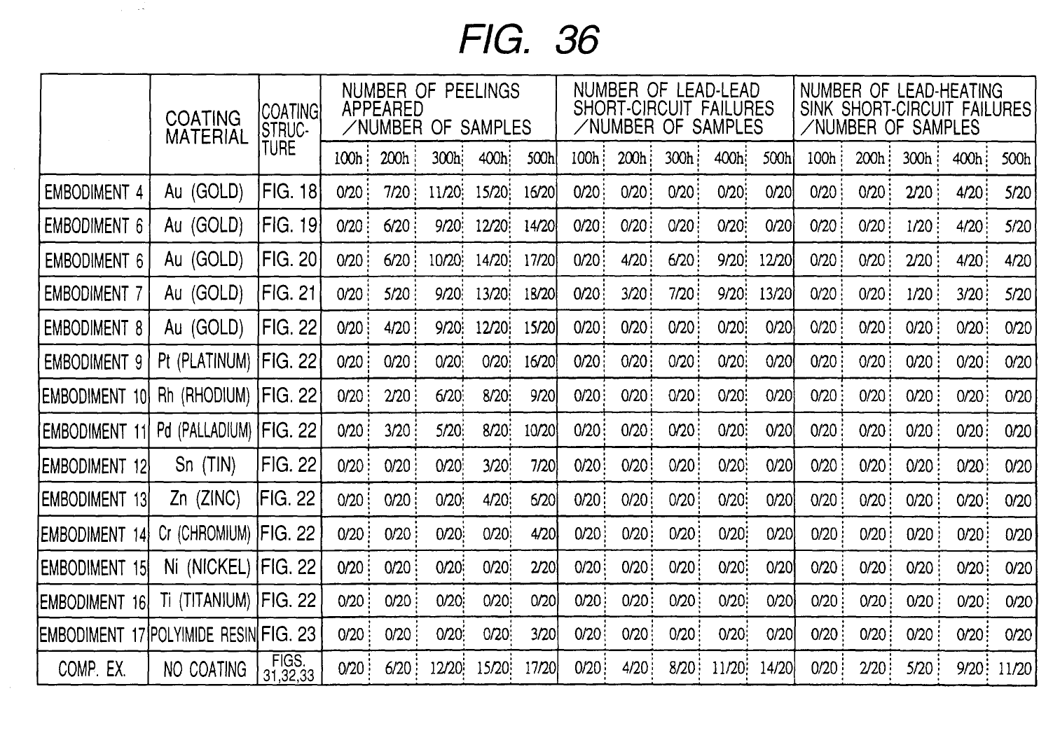

The additive serves to adjust the pH of the water at the peeling portion 9 to near neutral-so as not to cause elution of a copper material (Cu) into the peeling portion 9 formed along the interface between the inner lead 1a or the encapsulating resin 8 and the adhesive layer 2 as illustrated in FIG. 33, or the peeling portion 9 formed along the interface between the inner lead 1a and the encapsulating resin 8 as illustrated in FIG. 35.

It is therefore preferred to add, to the encapsulating resin 8, an additive capable of adjusting the pH of a resin extract available upon a pressure cooker test to 5.5 or greater but not greater than 10.

FIG. 6 is a graph illustrating one example of the relationship between the pH (hydrogen ion index) of the resin extract and the elution amount of copper. In FIG. 6, the shaded area is an area in which no Cu migration has occurred.

On the surface of copper or a copper alloy which is a material of the lead frame 1, an oxide film is formed spontaneously or by heat treatment such as wire bonding. This oxide film is dissolved (ionized) in an acid or alkali, depending on the acidic or alkaline circumstance, but is sparingly soluble at a near neutral pH of 5.5 or greater but not greater than 10. By the oxide film formed on the surface of copper, copper is passivated and therefore dissolution (ionization) of it hardly occurs.

When the pH of the resin extract is adjusted to 5.5 or greater but not greater than 10, the water at the peeling portion 9 becomes almost neutral. Such a pH prevents reaction of Cu and, in turn, elution of it. Deposition of copper is then suppressed, resulting in prevention of Cu migration.

Since Cu migration does not occur, short-circuit which will otherwise occur due to Cu migration can be inhibited.

The term “pressure cooker test” as used herein means a test conducted under the conditions of 121° C., 100% RH and 2 atm. The term “resin extract” as used herein means a solution extracted from the encapsulating resin 8 by allowing the semiconductor device to stand in pure water of 10 times the weight of the resin at 121° C. under 2 atm for 24 hours.

FIG. 7 is a graph illustrating one example of the relationship between the concentration (wt. %) of each of main additives added to adjust the pH of the resin extract to 5.5 or greater but not greater than 10 and the pH when it is added. Examples of the additive capable of neutralizing the extract include oxides, hydroxides and boroxides of an alkali metal (alkaline earth metal), more specifically, calcium oxide, magnesium hydroxide, barium borate, zinc borate, calcium metaborate and ion trapping agents (ion trappers).

By the addition of the additive, electroconductivity (microsiemens (μS)/cm) of the resin extract changes. FIG. 8 is a graph illustrating one example of the relationship between the concentration (wt. %) of each of the additives shown in FIG. 7 and electroconductivity (μS/cm) of the resin extract. The electroconductivity of the resin extract is preferably 100 μS/cm or less because excessively high electroconductivity causes too much flow of an electric current.

FIGS. 7 and 8 suggest that use of an ion trapping agent as an additive is preferred.

This ion trapping agent is a substance trapping anions or cations such as Cl⁻, Sb⁻, Br⁻, Na⁺ and SO₄²⁻ ions, so it can trap ionic impurities contained in the epoxy resin serving as the encapsulating resin 8 (can interfere with elution of the ionic impurities into the extract).

It can trap not only the ionic impurities in the encapsulating resin 8 but also those entering from the outside through the encapsulating resin 8.

Since the epoxy resin serving as the encapsulating resin 8 contains much Cl (chlorine) ions, ion trapping agents are suited also as an additive for forming a compound with a Cl⁻ ion.

The ion trapping agent is a DHA-4A hydrotalcite compound and specific examples include Mg_{4.3}Al₂(OH)_{12.6}CO₃.mH₂O (product of Kyowa Chemical Industry). It has a function of trapping ionic impurities, thereby maintaining the pH of the extract at neutral. Addition of a smaller amount of it brings about satisfactory effects, so that its influence on curing properties or strength of the encapsulating resin 8 can be minimized compared with another neutralizing agent.

In addition, even if the ion trapping agent is added in an amount greater than an estimated amount, it neither fails to adjust the extract to near neutral pH nor markedly increases the electroconductivity of the extract.

When an additive such as calcium oxide (CaO) which forms an aqueous alkali solution is added in an amount greater than an estimated amount, on the other hand, the aqueous solution becomes alkaline and the extract exhibits high electroconductivity. It therefore promotes elution of Cu so that severe control of its amount is indispensable.

If the above-described problem can be overcome, an alkaline additive can be added to the encapsulating resin 8.

In the HQFP 13 of Embodiment 1, as described above, water of the peeling portion 9 as illustrated in FIG. 33 or FIG. 35 becomes near neutral because the encapsulating resin 8 contains, as an additive, an ion trapping agent for adjusting the pH of the resin extract 8 to 5.5 or greater but not greater 10, and copper which is a material of the inner lead 1a or heat sink 3 is passivated by an oxide film formed on the surface of copper and is sparingly soluble (not ionized) in a pH range of from 5.5 to 10. This prevents reaction of copper and, in turn, elution of it, whereby deposition of copper can be avoided at the peeling portion 9.

This makes it possible to prevent occurrence of short-circuit and, in turn, Cu migration (second problem).

As a result, occurrence of short-circuit failures in PCT test can be prevented, whereby the reliability of the HQFP 13 (semiconductor device) can be improved.

A description will next be made of the fabrication procedure of the HQFP 13 of Embodiment 1. First, a lead frame equipped with a heat sink having an adhesive layer 2 formed thereon is prepared.

Over the adhesive layer 2 of the heat sink 3 which is a die pad (a portion to have a chip formed thereon) of the lead frame of the heat sink, a semiconductor element 4 is then die-bonded via an adhesive member 5, followed by wire bonding of the semiconductor element 4 and each of inner leads 1a via a metal wire 6.

Resin molding is then performed to encapsulate the semiconductor element 4 and a plurality of metal wires 6 with the encapsulating resin 8.

After encapsulation, the outer lead 1b is cut and bent into the gull-wing form, whereby the HQFP 13 is fabricated.

(Embodiment 2)

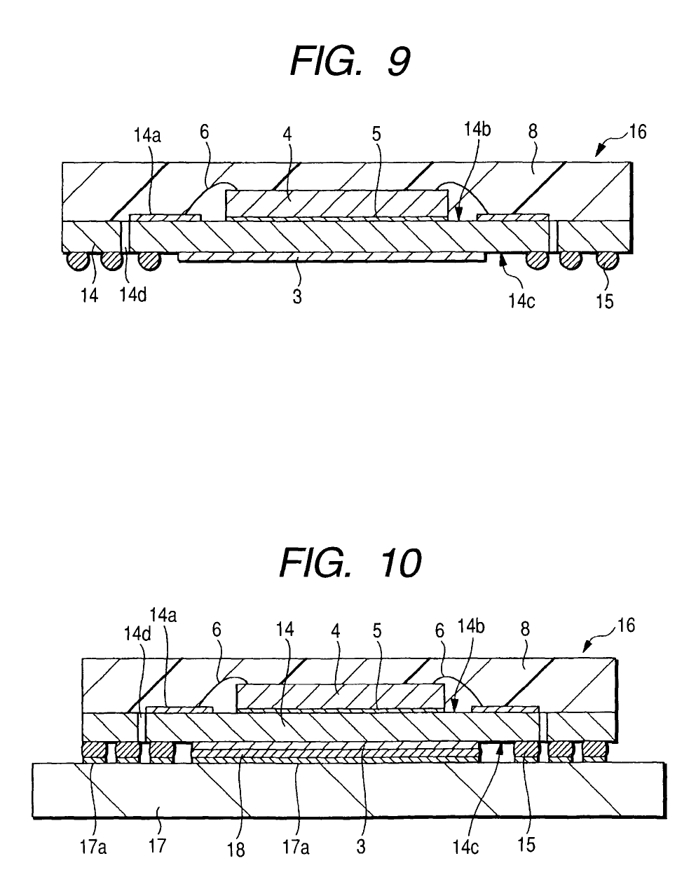

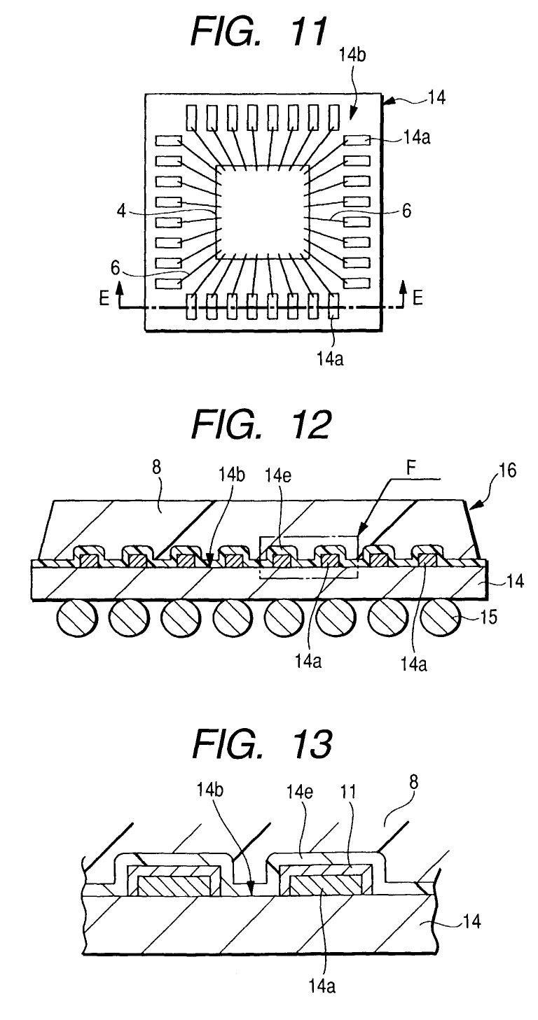

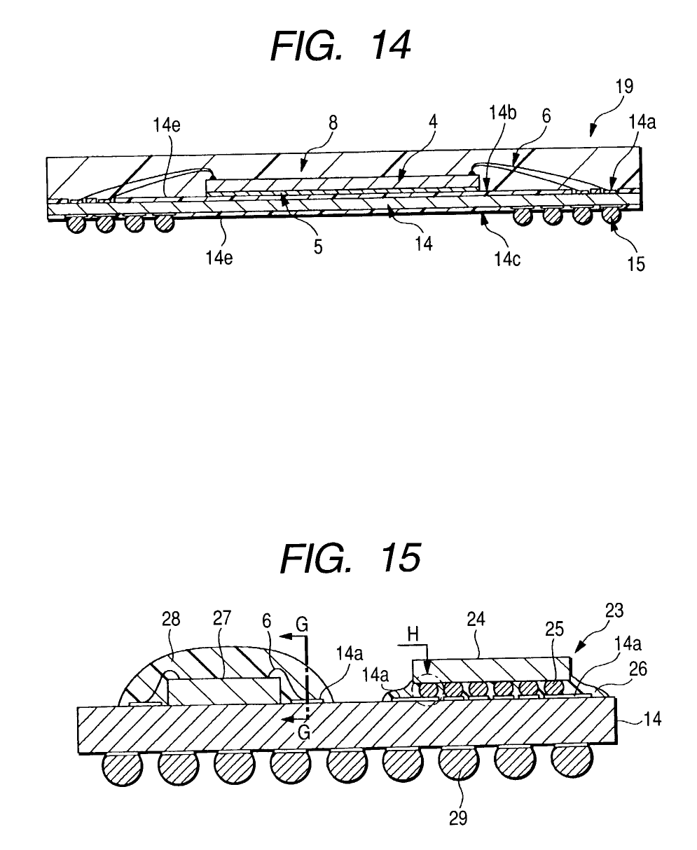

FIG. 9 is a cross-sectional view illustrating the structure of BGA which is one example of a semiconductor device according to Embodiment 2 of the present invention; FIG. 10 is a cross-sectional view illustrating the package structure of the BGA of FIG. 9; FIG. 11 is a plan view illustrating the inside structure of the BGA of FIG. 9; FIG. 12 is a cross-sectional view illustrating the structure taken along a line E-E of FIG. 11; FIG. 13 is an enlarged fragmentary cross-sectional view illustrating the structure of Portion F of FIG. 12; and FIG. 14 is a cross-sectional view illustrating the structure of another BGA, which is one example of the semiconductor device according to Embodiment 2 of the present invention.

The semiconductor device of Embodiment 2 as illustrated in FIG. 9 is BGA (ball grid array) 16 which has a wiring substrate 14 having a plurality of copper foil leads 14a, a semiconductor element 4 disposed over the element supporting surface 14b of the wiring substrate 14, a plurality of metal wires 6 (a plurality of metal bumps are also usable) for electrically connecting the semiconductor element 4 and the plurality of copper foil leads 14a, an encapsulating resin 8 for encapsulating therewith the plurality of metal wires 6 and the plurality of copper foil leads 14a, and a plurality of ball electrodes (protruding electrodes) 15 disposed on a back surface 14c which is a surface opposite to the surface on which the copper foil leads 14a of the wiring substrate 14 have been formed. As in the HQFP 13 of Embodiment 1, the encapsulating resin 8 contains an additive such as an ion trapping agent for adjusting the pH of the resin extract available upon the pressure cooker test to 5.5 or greater but not greater than 10.

On the element supporting surface 14b of the wiring substrate 14, a plurality of copper foil leads 14a are formed as illustrated in FIGS. 11 and 12 and each of the copper foil leads 14a is covered, at a portion other than a connected region with the metal wire 6, with an insulating solder resist film (resin protective film) 14e . Almost whole of the element supporting surface 14b including the copper foil leads 14a and solder resist film 14e is covered with the encapsulating resin 8. The BGA 16 has such a structure.

In addition, BGA 16 has a structure in which the surface of each of the copper foil leads 14a is covered with a metallic coating 11 such as gold plating and thereover, successively formed are the insulating solder resist film 14e and thereover, the encapsulating resin 8.

There are two methods for forming the metallic coating 11, that is, electroplating and electroless plating, and either can be employed.

In addition to this plating method, the metallic coating 11 can be formed by physical vapor deposition or chemical vapor deposition such as vacuum deposition, sputtering or ion plating.

As the wiring substrate 14, a glass-fiber-containing epoxy substrate or BT (bismaleimide.triazine) substrate, for example, is usable. As illustrated in FIG. 9, through an interconnect in a through-hole 14d formed in the substrate, the copper foil lead 14a on the element supporting surface 14b and the ball electrode 15 on the back surface 14c are electrically connected.

The encapsulating resin 8 is, for example, an epoxy resin.

FIG. 10 illustrates the packaged structure of the BGA 16 on an assembly substrate 17.

BGA 16 is a high heat dissipation type semiconductor device having a heat sink 3 attached on the back surface 14c of the wiring substrate 14 so that the ball electrode 15 is connected with a terminal 17a on the substrate side and at the same time, the heat sink 3 is connected with the terminal 17a via a soldering portion 18. By such a structure, heat dissipation property is heightened.

In the BGA 16 of this Embodiment 2, as in the HQFP 13 of Embodiment 1, an additive such as ion trapping agent for adjusting the pH of the resin extract to 5.5 or greater but not greater than 10 is added to the encapsulating resin 8, whereby pH of water can be made near neutral at the peeling portion of the copper foil lead 14a or the encapsulating resin 8 from the adhesive layer 2, or at a peeling portion of the heat sink end portion 3a from the encapsulating resin 8. In addition, copper, which is a material for the copper foil lead 14a or the heat sink 3, is passivated by an oxide film formed on the copper surface and is sparingly soluble (ionized). As a result, reaction of copper does not occur and elution of it is therefore suppressed, making it possible to prevent copper from being deposited at the above-described peeling portions.

By such a structure, occurrence of short-circuit can be prevented, and Cu migration (second problem) can be avoided.

As a result, occurrence of short-circuit failures upon PCT test can be prevented, whereby the reliability of BGA 16 can be improved.

It is desired to add, to the encapsulating resin 8, an additive capable of adjusting the electroconductivity of the resin extract to 100 μS/cm or less as in Embodiment 1. The other conditions of the additive are similar to those of Embodiment 1.

The additive may be added not only to the encapsulating resin 8 but also to the wiring substrate 14 or solder resist film 14e.

This means that occurrence of Cu migration can be prevented by the addition of the above-described additive to any one of the encapsulating resin 8, the base material (resin) of the wiring substrate 14 and solder resist film 14e.

Since the metallic coating 11 is formed on the surface of the copper foil lead 14a, deposition of Cu ion can be prevented and as a result, Cu migration (second problem) can be prevented owing to the effects of Embodiment 4, which will be described later, even if the substrate swells, absorbing moisture and peeling occurs between the copper foil lead 14a and solder resist film 14e or between the copper foil lead 14a and the encapsulating resin 8.

In particular when the metallic coating 11 is made of a metal such as tin (Sn), zinc (Zn), chromium (Cr), nickel (Ni) or titanium (Ti), or alternatively, it is an insulating film 11 such as polyimide resin, effects of Embodiments 12 to 17, which will be described later, make it possible to prevent both Cu migration (second problem) and formation of peeling (first problem).

The semiconductor device as illustrated in FIG. 14 is another BGA (ball grid array) 19. It uses, as the wiring substrate 14, a tape substrate made of a thin-film polyimide tape and is therefore compact in size.

This BGA 19 can bring about similar effects to those of BGA 16, because the encapsulating resin 8 has been added with an additive such as an ion trapping agent and on the surface of the copper foil lead 14a, a metallic coating 11 having a similar structure to that of FIG. 13 has been formed.

In the BGA 16 or BGA 19, the additive may be added to any one of the encapsulating resin 8, the base material (resin) of the wiring substrate 14 and the solder resist film 14e . The formation of the metallic coating 11 or insulating film 11 on the surface of the copper foil lead 14a is not always inevitable.

(Embodiment 3)

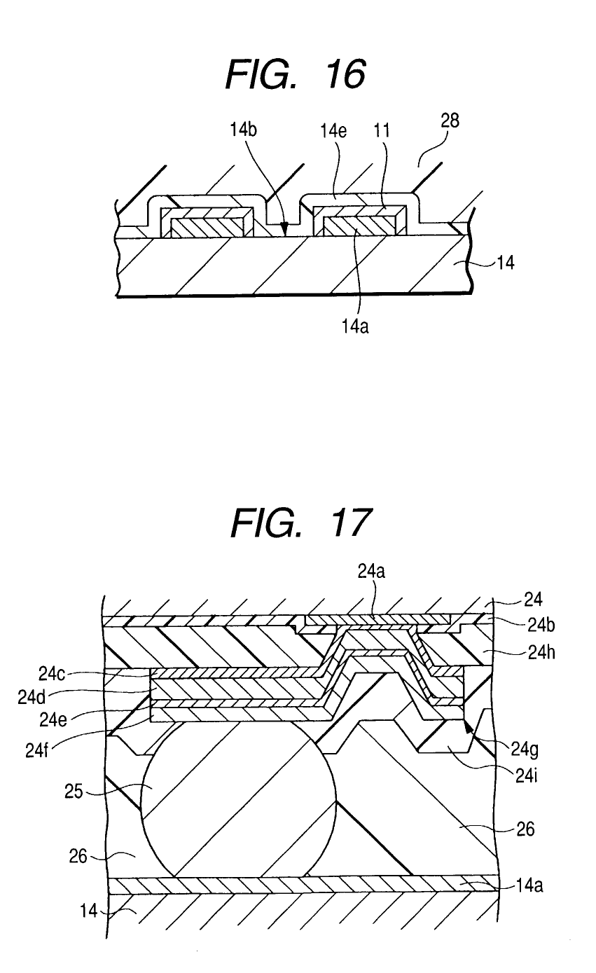

FIG. 15 is a cross-sectional view illustrating the structure of MCM which is one example of a semiconductor device according to Embodiment 3 of the present invention; FIG. 16 is an enlarged fragmentary cross-sectional view illustrating the structure taken along a line G-G of FIG. 15; and FIG. 17 is an enlarged fragmentary cross-sectional view illustrating the structure of Portion H of FIG. 15.

The semiconductor device of Embodiment 3 is MCM (multi-chip-module) 23 having a plurality of semiconductor elements.

The MCM 23 as illustrated in FIG. 15 has a wiring substrate 14 having thereon a plurality of copper foil leads 14a; a first semiconductor element 24 disposed over the wiring substrate 14 and having a Cu plating layer (copper interconnect) 24e, which is to be connected with a surface electrode exposed from the main surface, formed on the main surface; a plurality of bump electrodes (protruding electrodes) 25 electrically connecting the first semiconductor element 24 and each of the plurality of copper foil leads 14a of the wiring substrate 14; an underfill resin 26 disposed between the wiring substrate 14 and first semiconductor element 24 and covering the plurality of bump electrodes 25 with the resin; a second semiconductor element 27 disposed over the wiring substrate 14; a plurality of metal wires 6 for electrically connecting the second semiconductor element 27 and each of the plurality of copper foil leads 14a, a potting resin 28 which encapsulates therewith the second semiconductor element 27, plurality of metal wires 6 and plurality of copper foil leads 14a and is dropped on the wiring substrate 14; and a plurality of solder external electrodes 29 disposed on a back surface 14c of the wiring substrate 14.

In this MCM 23, an additive such as an ion trapping agent for adjusting the pH of a resin extract obtained upon the pressure cooker test to 5.5 or greater but not greater than 10 has been added to any one of the base material (resin) forming the wiring substrate 14, the solder resist film (resin protective film) 14e covering a portion of the copper foil lead 14a, the underfill resin 26 and the potting resin 28.

Here, MCM 23 having two semiconductor elements (first semiconductor element 24 and second semiconductor element 27) mounted thereon will be described, but the number of the semiconductor elements may be either one or plural and is not limited.

As illustrated in FIG. 17, each of the plurality of Al pads 24a on the main surface of the first semiconductor element 24 is covered, except for an exposed portion, with an insulating film 24b and it is electrically connected with the bump electrode 25 via rerouting 24g.

The rerouting 24g is made of, in the order starting from a layer on the side of the Al pad 24a, a Cr seed layer 24c, a Cu seed layer 24d, a Cu plated layer 24e and an Ni plated layer 24f.

The Cr seed layer 24c is protected by a first protective film 24h, while the Ni plated layer 24f is protected by a second protecting film 24i.

In other words, the first semiconductor element 24 serves as a CSP (chip size package) (or may be called “wafer process package”) having, on its main surface, the rerouting 24g having thereon the Cu plated layer 24e which is a copper interconnect and this rerouting 24g has the bump electrode 25 disposed thereon.

The MCM 23 has, as external terminals, a plurality of solder external electrodes 29 in the ball form and they are arranged in an array form with rows and columns on the back surface 14c of the wiring substrate 14.

In the second semiconductor element 27 of MCM 23, as illustrated in FIG. 16, the copper foil leads 14a each has a surface covered with independent metallic coating 11 such as gold plating, over which the insulating solder resist film 14e and the potting resin 28 are formed successively.

In the MCM 23 of Embodiment 3, any one of the base material (resin) forming the wiring substrate 14, the solder resist film (resin protective film) 14e covering a portion of the copper foil lead 14a, the underfill resin 26 an the potting resin 28 may contain the above-described additive. The formation of the metallic coating 11 on the surface of the copper foil lead 14a is not always necessary.

Such a structure of the MCM 23 of this Embodiment 3 disturbs reaction of copper in the Cu plated layer 24e or copper foil lead 14a and suppresses Cu elution, whereby Cu migration can be prevented.

As in the Embodiment 1, it is preferred to add an additive for adjusting the electroconductivity of the resin extract to 100 μS/cm or less. The other conditions of the additive are similar to those of Embodiment 1.

Since the metallic coating 11 is formed on the surface of the copper foil lead 14a, deposition of Cu ion can be blocked and as a result, Cu migration can be prevented owing to the effects of Embodiment 4, which will be described later, even if the substrate swells with absorbed moisture and peeling occurs between the copper foil lead 14a and solder resist film 14e or between the copper foil lead 14a and the encapsulating resin 8.

A description will next be made of Embodiments 4 to 19.

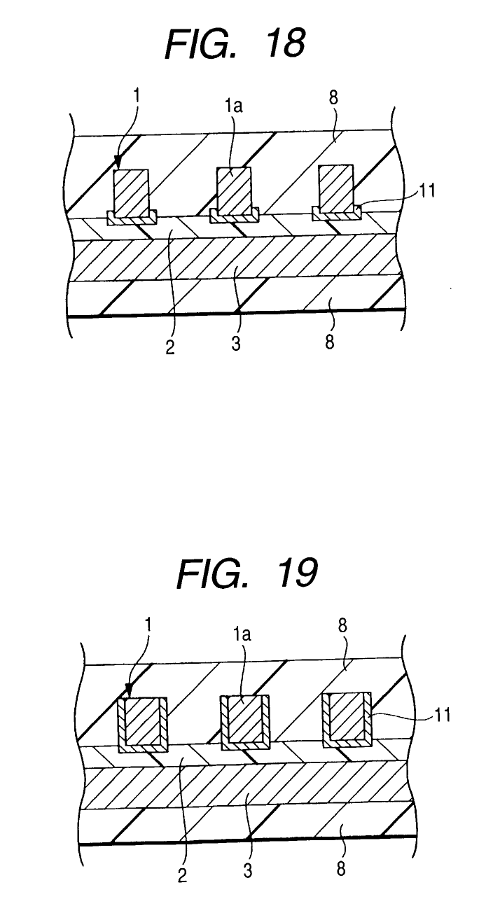

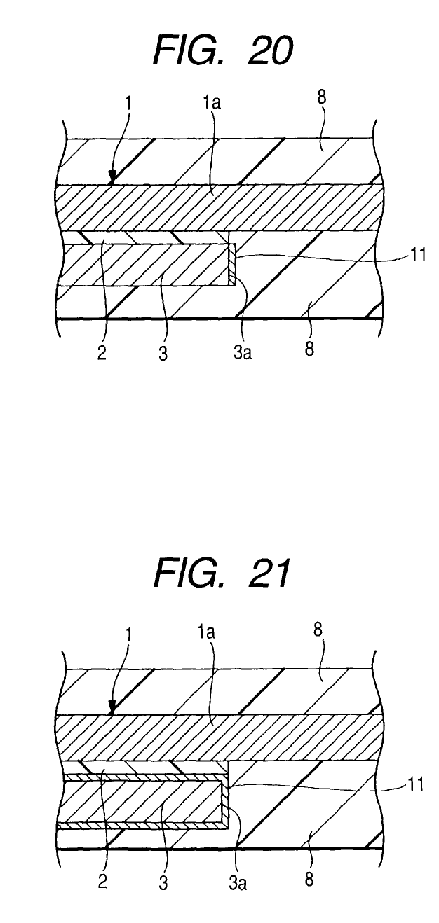

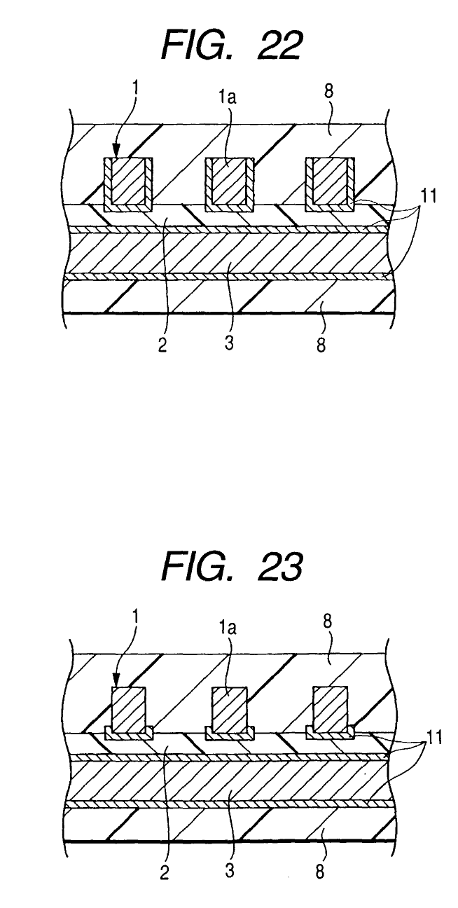

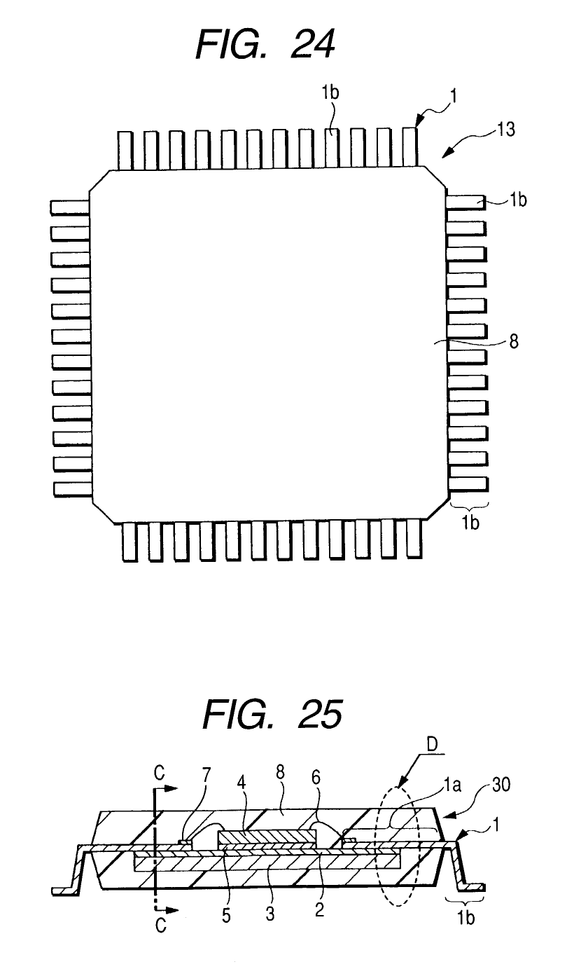

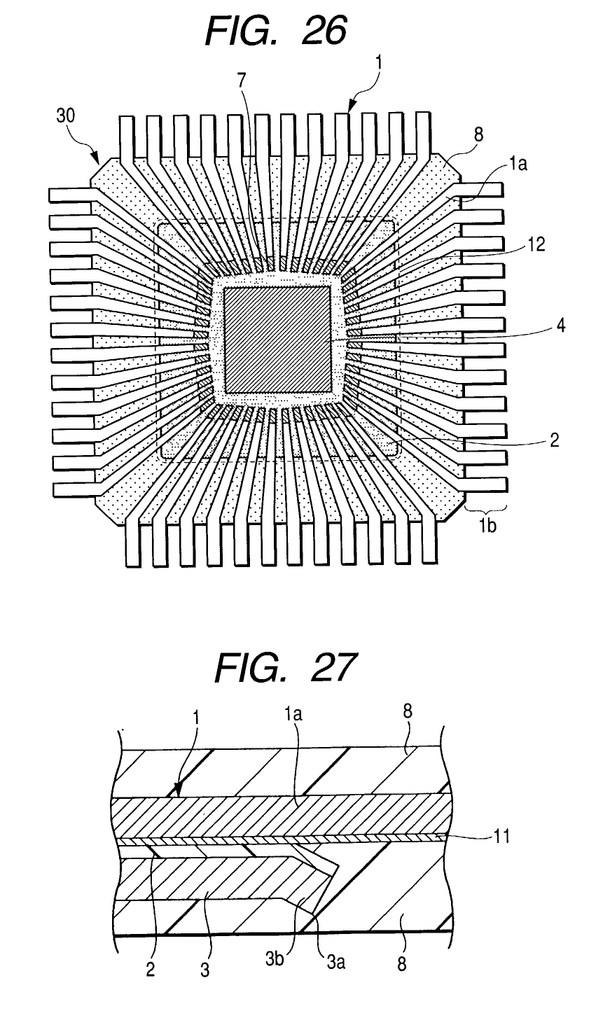

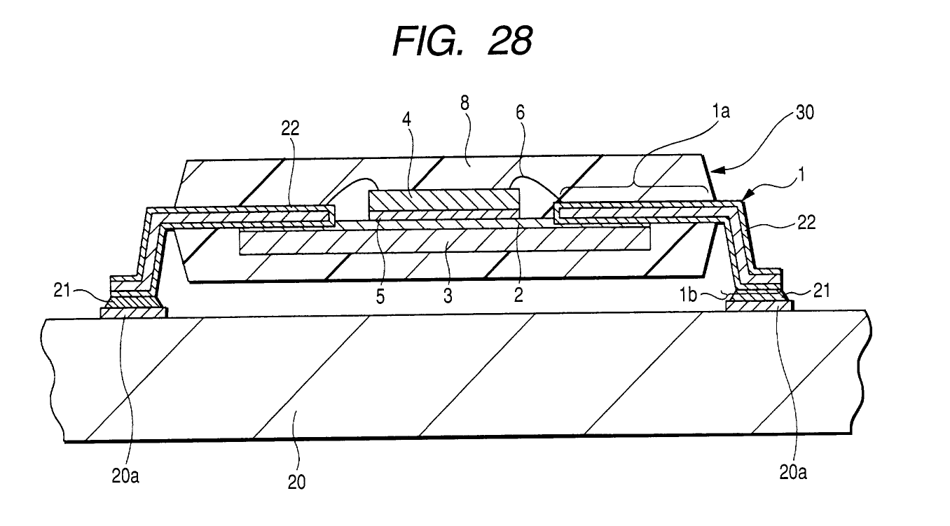

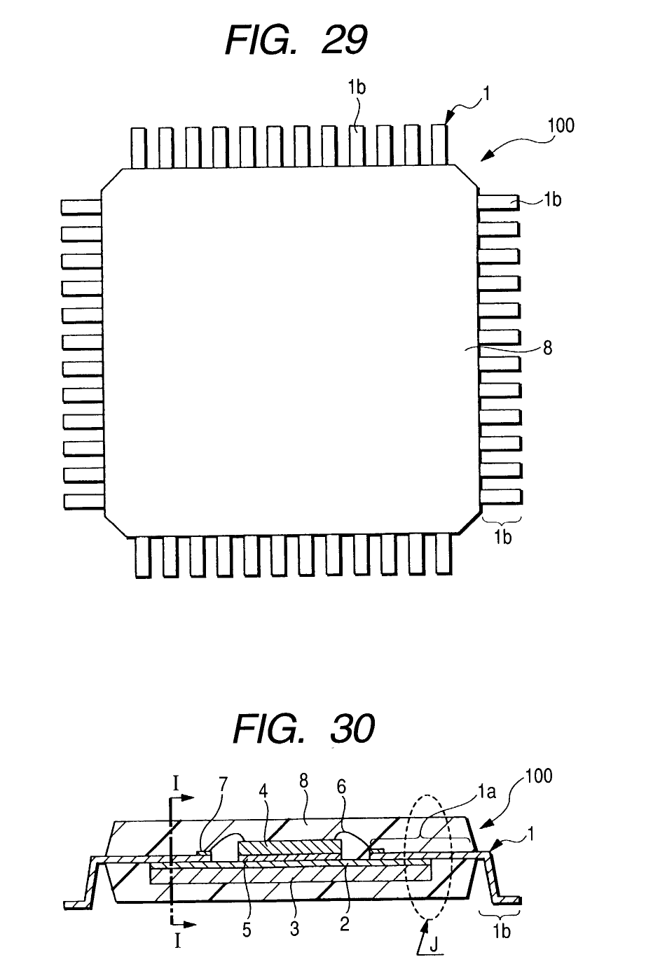

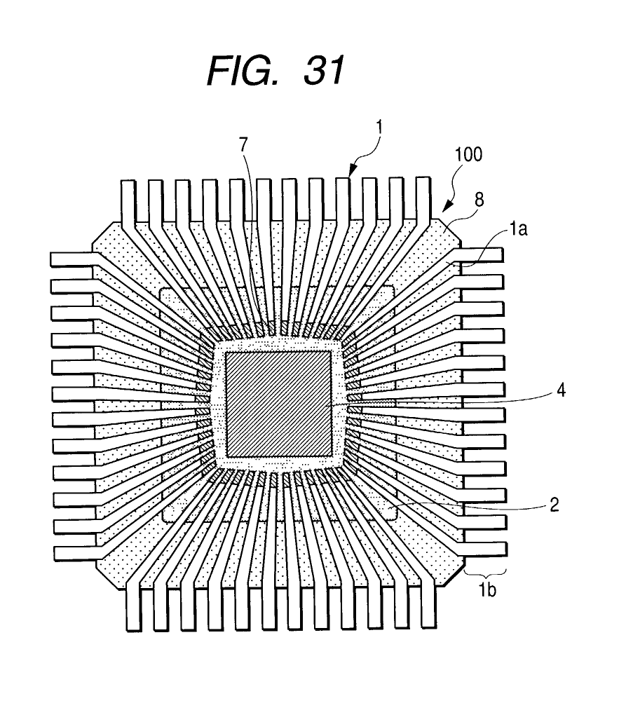

FIG. 18 illustrates the structure of HQFP which is one example of a semiconductor device according to Embodiment 4 of the present invention; FIG. 19 is an enlarged fragmentary cross-sectional view illustrating the structure of HQFP which is one example of a semiconductor device according to Embodiment 5 of the present invention; FIG. 20 is an enlarged fragmentary cross-sectional view illustrating the structure of HQFP which is one example of a semiconductor device according to Embodiment 6 of the present invention; FIG. 21 is an enlarged fragmentary cross-sectional view illustrating the structure of HQFP which is one example of a semiconductor device according to Embodiment 7 of the present invention; FIG. 22 is an enlarged fragmentary cross-sectional view illustrating the structure of HQFP which is one example of a semiconductor device according to Embodiment 8 of the present invention; FIG. 23 is an enlarged fragmentary cross-sectional view illustrating the structure of HQFP which is one example of a semiconductor device according to Embodiment 17 of the present invention; FIG. 24 is a plan view illustrating the structure of the HQFP according to Embodiment 4 of the present invention; FIG. 25 is a cross-sectional view illustrating the structure of HQFP illustrated in FIG. 24; FIG. 26 is a plan view illustrating the inside structure of the HQFP illustrated in FIG. 24; FIG. 27 is an enlarged fragmentary cross-sectional view illustrating the structure of Portion D illustrated in FIG. 25; FIG. 28 is an enlarged fragmentary cross-sectional view illustrating one example of the semiconductor device (HQFP) of the present invention which has a lead plated, on the whole surface thereof, with Pd and is packaged by Pb-free (lead) soldering; and FIG. 36 shows evaluation results, by a pressure cooker test, of moisture resistance of the semiconductor devices (HQFPs) of the present invention upon covering a lead with a metal or resin without adding an additive to an encapsulating resin.

(Embodiment 4)

FIG. 18 illustrates the cross-sectional structure of HQFP 30 which is a semiconductor device according to Embodiment 4 of the present invention using a lead frame equipped with a heat sink. It is an enlarged cross-sectional view taken along a line C-C of FIG. 25.

An encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

As illustrated in FIG. 18, metallic coating 11 is formed by plating, with gold (Au) in advance, the whole portion of the lead frame 1 to be joined with the adhesive layer 2. For plating, either electroplating or electroless plating is usable.

A region of each of the inner leads 1a to have the metallic-coating 11 formed thereon is a metallic coating region 12 (which equally applies to an insulating film region) illustrated in FIG. 26. It corresponds to the whole region in which an interface between the encapsulating resin 8 or inner lead 1a and the adhesive layer 2 is to be formed and peeling presumably occurs, moreover a region of each of the inner leads 1a extending from the vicinity of the end portion on the side of the chip to a little outside of a portion to be joined with the adhesive layer 2.

This metallic coating 11 can be formed not only by plating but also by physical vapor deposition or chemical vapor deposition such as vacuum deposition, sputtering or ion plating. After formation of the metallic coating, the heat sink 3 having the adhesive layer 2 formed thereon in advance is adhered to the lead frame 1, whereby a lead frame with a heat sink is formed. Subsequent steps for fabrication of the semiconductor device are carried out in a conventional manner.

(Embodiment 5)

FIG. 19 illustrates the cross-sectional structure of HQFP 30 which is a semiconductor device using a lead frame with a heat sink according to Embodiment 5 of the present invention. FIG. 19 is an enlarged cross-sectional view taken along a line C-C of FIG. 25.

The encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

As illustrated in FIG. 19, metallic coating 11 is formed by plating, with gold (Au) in advance, the whole portion of the lead frame 1 to be joined with the adhesive layer 2 and the side surface portion of the lead. After formation of the metallic coating, the heat sink 3 having the adhesive layer 2 formed thereon in advance is adhered to the lead frame 1, whereby the lead frame with a heat sink is obtained. Subsequent steps for the fabrication of the semiconductor device are carried out in a conventional manner.

(Embodiment 6)

FIG. 20 is a cross-sectional view of HQFP 30 which is a semiconductor device using a lead frame with a heat sink according to Embodiment 6 of the present invention, in which illustrated is the periphery of the end portion of the heat sink. FIG. 20 is an enlarged view of Portion D of FIG. 25.

The encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

As illustrated in FIG. 20, metallic coating 11 is formed by plating the heat sink end portion 3a with gold (Au) in advance. After formation of the metal film, a heat sink 3 having the adhesive layer 2 formed thereon in advance is adhered to the lead frame 1, whereby the lead frame with a heat sink is obtained. Subsequent steps for the fabrication of the semiconductor device are carried out in a conventional manner.

(Embodiment 7)

FIG. 21 is a cross-sectional view of HQFP 30 which is a semiconductor device using a lead frame with a heat sink according to Embodiment 7 of the present invention, in which illustrated is the periphery of the end portion of the heat sink. FIG. 21 is an enlarged view of Portion D of FIG. 25.

The encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

As illustrated in FIG. 4, metallic coating 11 is formed by plating the whole circumference of the heat sink 3 with gold (Au) in advance. After formation of the metallic coating, an adhesive layer 2 is formed on one plane of the heat sink 3 and the resulting heat sink is adhered to the lead frame 1, whereby a lead frame with a heat sink is obtained. Subsequent steps for the fabrication of the semiconductor device are carried out in a conventional manner.

(Embodiment 8)

FIG. 22 illustrates a cross-sectional structure of HQFP 30 which is a semiconductor device using a lead frame with a heat sink according to Embodiment 8 of the present invention. FIG. 22 is an enlarged cross-sectional view taken along a line C-C of FIG. 25.

The encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

As illustrated in FIG. 22, metallic coating 11 is formed by plating, with gold (Au) in advance, the whole portion of the lead frame 1 to be joined with the adhesive layer 2, the side surface portion of the lead and the whole circumference of the heat sink 3. After formation of the metallic coating, an adhesive layer 2 is formed on one plane of the heat sink 3 and the resulting heat sink is adhered to the lead frame 1, whereby a lead frame with a heat sink is obtained. Subsequent steps for the fabrication of the semiconductor device are carried out in a conventional manner.

(Embodiments 9 to 16)

The structure is similar to that of Embodiment 8 illustrated in FIG. 22 except that metallic coating 11 is formed by plating the whole portion of the lead frame 1 to be joined with the adhesive layer 2 and the whole circumference of the heat sink 3 in advance with platinum (Pt) (Embodiment 9), rhodium (Rh) (Embodiment 10), palladium (Pd) (Embodiment 11), tin (Sn) (Embodiment 12), zinc (Zn) (Embodiment 13), chromium (Cr) (Embodiment 14), nickel (Ni) (Embodiment 15) or titanium (Ti) (Embodiment 16).

The encapsulating resin 8 has been added with an additive such as an ion trapping agent capable of controlling the pH of the resin extract to 5.5 or greater but not greater than 10. As in Embodiment 1, it is preferred to add, to the encapsulating resin 8, an additive for controlling the electroconductivity of the resin extract to 100 μS/cm or less. The other conditions of the additive are similar to those of Embodiment 1.

After formation of the metallic coating, an adhesive layer 2 is formed on one plane of the heat sink 3 and the resulting heat sink is adhered to the lead frame 1, whereby a lead frame with a heat sink is obtained. Subsequent steps for the fabrication of the semiconductor device are carried out in a conventional manner.

(Embodiment 17)

FIG. 23 is an enlarged view of the cross-section taken along a line C-C of FIG. 25. The encapsulating resin 8 has been added with an additive such as an ion trapping agent for controlling the pH of the resin extract to 5.5 or greater but not greater than 10. An insulating film 11 is formed by applying a polyimide resin varnish, in advance, to the whole portion of a lead frame 1 to be joined with an adhesive layer 2 and the whole circumference of a heat sink 3, and then drying the film. For the formation of this insulating film 11, not only polyimide resin but also another insulating resin such as phenol, epoxy or polyamide may be used.

An inorganic substance such as alumina or silica may be mixed as a filler in an insulating resin in order to improve heat conductivity of the insulating film 11 and moreover, to adjust the thermal expansion coefficients of the members to the same level.

After formation of the insulating film, the adhesive layer 2 is formed on one plane of the heat sink 3. The resulting heat sink is then adhered to the lead frame 1 whereby the lead frame with a heat sink is obtained. Subsequent steps for the fabrication of the semiconductor device are conducted in a conventional manner.

A description will next be made of the evaluation results of the moisture resistance of each structure.

FIG. 36 shows the evaluation results of PCT (pressure cooker test) on moisture resistance of the HQFP 30 of each of Embodiments 4 to 17 having the structure as shown in FIGS. 18 to 23 when the encapsulating resin 8 is free of an additive such as ion trapping agent.

The PCT test is performed under the conditions of 121° C., 100% RH and 2 atm.

As illustrated in FIG. 36, in the conventional HQFP of Comparative Example (no metallic coating), peeling occurred (first problem) approximately 200 hours after the PCT was started and short-circuit failures occurred between lead and lead or lead and heat sink (second problem). The semiconductor devices obtained in Embodiments 4 to 17 according to the present invention, on the other hand, were free from short-circuit failures or, if any, less than those obtained in Comparative Example, thus exhibiting good results.

Evaluation results of moisture resistance of the semiconductor devices obtained in Embodiments 4 to 17 will next be described more specifically.

In Embodiment 4 (FIG. 18) and Embodiment 5 (FIG. 19), peeling occurred approximately 200 hours after the beginning of PCT, which was similar to Comparative Example. But, no migration between lead and lead occurred. Between lead and heat sink, however, migration occurred approximately 300 hours after PCT was started, because the heat sink end portion 3a had no coating.

Also in Embodiment 6 (FIG. 20) and Embodiment 7 (FIG. 21), peeling occurred approximately 200 hours after the beginning of PCT, which was similar to Comparative Example. Between lead and lead, however, migration occurred as in Comparative Example, because the lead frame 1 had no coating. Migration between lead and heat sink was less frequent than that of Comparative Example, but was not prevented completely.

In Embodiment 8 (FIG. 22), peeling occurred approximately 200 hours after the starting of PCT, which was similar to Comparative Example. No migration, however, occurred between lead and lead, and lead and heat sink.

As in Comparative Example, peeling occurred in Embodiment 9 illustrated in FIG. 22 in which platinum was used for metallic coating, in Embodiment 10 in which rhodium was used for metallic coating, and in Embodiment 11 in which palladium was used for metallic coating, approximately 200 hours after the PCT was started. Migration however did not occur because elution from the surface covered with platinum, rhodium or palladium, similar to that covered with gold, did not occur easily by acidic water, making it possible to prevent lead-lead and lead-heat sink short-circuit failures.

As described above, according to Embodiments 4 to 11 shown in FIG. 36, the second problem (Cu migration) can be overcome.

In Embodiment 12 in which tin was used and Embodiment 13 in which zinc was used, no peeling occurred until 300 hours after the beginning of the PCT, which is presumed to result from that the adhesive force of the adhesive became stronger when the surface is covered with tin or zinc than the copper surface. Even after peeling occurred, neither migration nor lead-lead and lead-heat sink short-circuit failures appeared, because tin is superior to copper in resistance to acid elution or zinc ion does not elute in spite of the corrosion of the zinc surface.

In Embodiment 14 in which chromium was used and in Embodiment 15 in which nickel was used, no peeling occurred until 400 hours after the beginning of PCT, which is presumed to result from that the adhesive force between the surface covered with chromium or nickel and the adhesive became higher than that between the copper surface and the adhesive. After peeling appears, neither chromium nor nickel elutes easily under acidic water environment compared with copper. As a result, neither migration nor lead-lead and lead-heat sink short-circuit failures occurred.

In Embodiment 16 in which titanium was used, peeling did not appear until 500 hours after the beginning of PCT, which is presumed to result from that the adhesive force of the surface covered with titanium became stronger than that of the copper surface. After peeling, a passivation film having oxidation resistance was formed on the titanium surface, which prevents easy elution. As a result, neither migration, nor lead-lead and lead-heat sink short-circuit failures occurred.

In Embodiment 17 in which a polyimide resin was used, peeling did not occur until 400 hours after PCT was started. Small number of samples peeled 500 hours after the starting of PCT. This peeling occurred not between the lead frame 1 and the insulating film 11 made of a polyimide resin or the heat sink 3 and the insulating film 11 but between the insulating film 11 and the adhesive layer 2. This is presumed to occur because the insulating film 11 obtained by applying a polyimide resin varnish onto a metal such as copper and then drying had a high adhesive force. As a result, neither migration nor lead-lead and lead-heat sink short-circuit failures occurred.

As described above, according to Embodiments 12 to 17 shown in FIG. 36, the first problem (formation of peeling), as well as the second problem (Cu migration) can be overcome.

(Embodiment 18)

FIG. 27 illustrates the structure of Embodiment 18 and is an enlarged view of Portion D of FIG. 25. The encapsulating resin 8 has been added with an additive such as ion trapping agent for controlling the pH of the resin extract to 5.5 or greater but not greater than 10.

At the periphery of the heat sink 3, a flexion 3b which is a portion bent in the direction apart from the inner lead 1a is formed. This structure is combined with the structure of Embodiment 4 illustrated in FIG. 18 or the structure of Embodiment 5 illustrated in FIG. 19.

Owing to this flexion, a space appears between the inner lead 1a and the heat sink end portion 3a, making it possible to prevent occurrence of Cu migration between lead and heat sink.

Described specifically, the structure shown in FIG. 18 or FIG. 19 was free from lead-lead short-circuit failures, but was not free from lead-heat sink short-circuit failures as a result of humidity resistance evaluation shown in FIG. 36. By simply using the structure of FIG. 18 or FIG. 19 in combination with the structure of FIG. 27, even the short circuit between the lead and heat sink can be prevented.

Use of, as metallic coating 11 to be formed over the inner lead 1a as described in Embodiments 4 to 18, an underlying nickel (Ni) plating and whole palladium (Pd) plating in combination makes it possible to omit the external plating or Ag plating of the tip of the inner lead, thereby simplifying the fabrication step.

Described specifically, use of Pd plating 22, as in the structure of Embodiment 19 shown in FIG. 25, makes it possible to maintain wetness between the lead and solder to be used for mounting the HQFP 30 on the wiring substrate 20, thereby omitting the external plating step which has so far applied to the tip of the outer lead 1b, and at the same time actualizing the structure free of Pb (lead) which has so far been used for external plating of the outer lead 1b (adoption of Pb-free structure).

In particular, when a Pb-free semiconductor device is aimed at, prevention of migration between Cu leads and fabrication of a Pb-free semiconductor device can be actualized simultaneously by mounting, on the wiring substrate 20 via a Pb-free solder 21 connected with the substrate-side terminal 20a, the HQFP 13 using the lead frame 1 having the inner lead 1a and outer lead 1b simultaneously subjected to Pd plating 22 as shown in FIG. 25.

Use of the Pd plating 22 secures connection of a portion of the inner lead 1a to be connected with the metal wire 6, whereby Ag plating 7 for connecting metal wire, which has so far been applied to the inner lead 1a, can be omitted.

By adopting tin (Sn) plating as metallic coating 11 to be formed on the inner lead 1a, it becomes possible to carry out wire bonding directly on the Sn plating after breaking the oxide film on the surface.

This makes it possible to form the metallic coating 11 which also serves as external plating so that an external plating step can be omitted and at the same time, a Pb-free device can be actualized.

As a metal to form the metallic coating 11 over the inner lead 1a or the copper foil lead 14a as described in Embodiment 1, and Embodiment 4 (FIG. 18) to Embodiment 19 (FIG. 28), any metal is usable insofar as it does not cause Cu migration easily.

As metals which form the metallic coating 11, metals having a reference electrode potential higher than that of copper (Cu) are usable in the present invention. Examples include gold (Au), platinum (Pt), iridium (Ir), rhodium (Rh), palladium (Pd) and silver (Ag). Of these, one or more metals or alloys thereof may be used.

Metals which form a passivation film under acidic conditions are also usable. Examples include ruthenium (Ru), indium (In), tin (Sn), molybdenum (Mo), tungsten (W), gallium (Ga), zinc (Zn), chromium (Cr), niobium (Nb), tantalum (Ta), titanium (Ti), zirconium (Zr), osmium (Os), aluminum (Al), hafnium (Hf) and nickel (Ni). Of these, one or more metals or alloys thereof may be used.

The present invention made by the present inventor was described above specifically based on Embodiments of the present invention. It is needless to say that the present invention is not limited to or by these embodiments of the present invention and can be changed without departing from the gist of the present invention.

For example, in the above-described Embodiments, HQFP was taken up as a semiconductor device using a lead frame with a heat sink. The present invention is not limited to an HQFP type semiconductor device having a heat sink of a high heat conductivity but can be adapted to a QFP type semiconductor device with a substrate which device intends to maintain the strength of the tip of the inner lead upon resin encapsulating step by fixing the tip of the inner lead onto the substrate when the tip of the inner lead becomes narrow under tendency to more pins with smaller pitches.

Even in such a structure, when there is a difference in a thermal expansion coefficient between the substrate and the encapsulating resin and the stress resulting therefrom causes peeling along the interface between the substrate and encapsulating resin, it is effective to take countermeasures against migration of Cu lead according to the present invention.

Of the inventions disclosed by the present application, the typical ones will next be summarized briefly.

Since the additive to control the pH of the resin extract to 5.5 or greater but not greater than 10 is added to the resin such as encapsulating resin of the semiconductor device, water at the peeling portion becomes near neutral. In a pH range of 5.5 or greater but not greater than 10, copper is passivated by the oxide film formed on its surface and therefore is sparingly insoluble in the water. Without reaction of copper, elution of copper does not occur easily, making it possible to prevent deposition of copper at the peeling portion. By this, short circuit and also Cu migration can be prevented. As a result, generation of short-circuit failures upon PCT test can be prevented, leading to an improvement in the reliability of the semiconductor device.

What is claimed is:

1. A semiconductor device, comprising:
a semiconductor element;
a plurality of leads each made of copper or an alloy thereof and disposed around the periphery of said semiconductor element;
a plurality of metal wires each electrically connecting said semiconductor element and each of said plurality of leads; and
an encapsulating resin encapsulating therewith said semiconductor element, said plurality of leads, and said plurality of metal wires,
said encapsulating resin having been added with an additive forming a compound with an ionic impurity.

2. A semiconductor device, comprising:
a semiconductor element;
a plurality of leads each made of copper or an alloy thereof and disposed around the periphery of said semiconductor element;
a plurality of metal wires each electrically connecting said semiconductor element and each of said plurality of leads; and
an encapsulating resin encapsulating therewith said semiconductor element, said plurality of leads, and said plurality of metal wires,
said encapsulating resin having been added with an additive for adjusting the pH of a resin extract available upon a pressure cooker test to 5.5 or greater but not greater than 10.

3. A semiconductor device, comprising:
a semiconductor element;
a plurality of inner leads each made of copper or an alloy thereof and extending around the periphery of said semiconductor element;
a heat sink which is made of copper or an alloy thereof and is connected to one end of each of said plurality of inner leads via an insulating adhesive layer, and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink, and having a coefficient of thermal expansion smaller than that of said adhesive layer,
said encapsulating resin having been added with an ion trapping agent.

4. A semiconductor device, comprising:
a semiconductor element;
a plurality of inner leads each made of copper or an alloy thereof and extending around the periphery of said semiconductor element;
a heat sink which is made of copper or an alloy thereof and is connected to one end of each of said plurality of inner leads via an insulating adhesive layer, and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
said encapsulating resin having been added with an additive for adjusting the pH of a resin extract available upon a pressure cooker test to 5.5 or greater but not greater than 10.

5. A semiconductor device according to claim 4, wherein said resin extract has an electroconductivity of 100 microsiemens/cm or less.

6. A semiconductor device according to claim 4, wherein said encapsulating resin is an epoxy resin.

7. A semiconductor device, comprising:
a semiconductor element;
a plurality of inner leads each made of copper or an alloy thereof and extending around the periphery of said semiconductor element;
a heat sink which is made of copper or an alloy thereof and is connected to one end of said plurality of inner leads via an insulating adhesive layer, and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
said encapsulating resin having been added with an additive forming a compound with a chlorine ion.

8. A semiconductor device according to claim 7, wherein said additive is an ion trapping agent.

9. A semiconductor device, comprising:
a semiconductor element;
a plurality of inner leads each made of copper or an alloy thereof and extending around the periphery of said semiconductor element;
a heat sink which is made of copper or an alloy thereof and is connected to one end of each of said plurality of inner leads via an insulating adhesive layer, and on which said semiconductor element is to be mounted via said adhesive layer;
a plurality of metal wires each electrically connecting said semiconductor element to each of said plurality of inner leads; and
an encapsulating resin encapsulating therewith said semiconductor element, said plurality of inner leads, said plurality of metal wires, and said heat sink,
said encapsulating resin having been added with an alkaline neutralizer.

10. A semiconductor device, comprising:
a semiconductor element;
a plurality of inner leads each made of copper or an alloy thereof and extending around the periphery of said semiconductor element;
a heat sink which is made of copper or an alloy thereof and is connected to one end of each of said plurality of inner leads via an insulating adhesive layer, and on which said semiconductor element is to be mounted via said adhesive layer;
a plurality of metal wires electrically connecting said semiconductor element and each of said plurality of inner leads; and
an encapsulating resin encapsulating therewith said semiconductor element, said plurality of inner leads, said plurality of metal wires, and said heat sink,
said encapsulating resin having been added with an ion trapping agent forming a compound with an ionic impurity.

11. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
said encapsulating resin having been added with an additive for adjusting the pH of a resin extract available upon a pressure cooker test to 5.5 or greater but not greater than 10.

12. A semiconductor device according to claim 11, wherein said encapsulating resin is an epoxy resin.

13. A semiconductor device according to claim 11, wherein said resin extract has an electroconductivity of 100 microsiemens/cm or less.

14. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads,
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
said wiring substrate being made of a resin having been added with an additive for adjusting the pH of a resin extract available upon a pressure cooker test to 5.5 or greater but not greater than 10.

15. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
each of said plurality of copper foil leads of said wiring substrate being partially covered with a resin protective film which has been added with an additive for adjusting the pH of a resin extract available upon a pressure cooker test to 5.5 or greater but not greater than 10.

16. A semiconductor device, comprising:
a wiring substrate having a plurality of copper foil leads;
a semiconductor element disposed over said wiring substrate and having, on the main surface of said semiconductor element, a copper interconnect to be connected with a surface electrode exposed from the main surface;
a plurality of protruding electrodes each electrically connecting said semiconductor element and each of said plurality of copper foil leads of said wiring substrate; and
an underfill resin disposed between said wiring substrate and said semiconductor element and covering said plurality of protruding electrodes,
said underfill resin having been added with an additive for adjusting the pH of a resin extract available upon a pressure cooker test to 5.5 or greater but not greater than 10.

17. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
a potting resin encapsulating therewith said semiconductor element, said plurality of metal wires, and said plurality of copper foil leads, and having been dropped onto said wiring substrate; and
a plurality of protruding electrodes disposed on a side of said wiring substrate opposite to the side on which said copper foil leads have been formed,
said potting resin having been added with an additive for adjusting the pH of a resin extract available upon a pressure cooker test to 5.5 or greater but not greater than 10.

18. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
said encapsulating resin having been added with an additive for forming a compound with a chlorine ion.

19. A semiconductor device according to claim 18, wherein said additive is an ion trapping agent.

20. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed over a side of said wiring substrate opposite to the side on which said copper foil leads have been formed,
said encapsulating resin having been added with an alkaline neutralizer.

21. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
said encapsulating resin having been added with an ion trapping agent for forming a compound with an ionic impurity.

22. A semiconductor device, comprising:
a semiconductor element;
a plurality of inner leads each made of copper or an alloy thereof and extending around said semiconductor element;
a heat sink which is bonded to one end of each of said plurality of inner leads via an insulating adhesive layer and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal having a reference electrode potential higher than that of copper, and said encapsulating resin has been added with an additive for controlling the pH of a resin extract available upon a pressure cooker test to 5.5 or greater but not greater than 10.

23. A semiconductor device, comprising:
a semiconductor element;
a plurality of inner leads each made of copper or an alloy thereof and extending around said semiconductor element;
a heat sink which is bonded to one end of each of said plurality of inner leads via an insulating adhesive layer and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal having a reference electrode potential higher than that of copper, and said encapsulating resin has been added with an additive forming a compound with a chlorine ion.

24. A semiconductor device, comprising:
a semiconductor element;
a plurality of inner leads each made of copper or an alloy thereof and extending around said semiconductor element;
a heat sink which is bonded to one end of each of said plurality of inner leads via an insulating adhesive layer and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal having a reference electrode potential higher than that of copper, and said encapsulating resin has been added with an ion trapping agent for forming a compound with an ionic impurity.

25. A semiconductor device, comprising:
a semiconductor element;
a plurality of inner leads each made of copper or an alloy thereof and extending around said semiconductor element;
a heat sink which is bonded to one end of said plurality of inner leads via an insulating adhesive layer and on which said semiconductor element is to be mounted via said adhesive layer;
a plurality of metal wires electrically connecting said semiconductor element to each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal forming a passivation film under acidic conditions, and said encapsulating resin has been added with an additive for controlling the pH of a resin extract available upon a pressure cooker test to 5.5 or greater but not greater than 10.

26. A semiconductor device, comprising:
a semiconductor element;
a plurality of inner leads each made of copper or an alloy thereof and extending around said semiconductor element;
a heat sink which is bonded to one end of said plurality of inner leads via an insulating adhesive layer and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal forming a passivation film under acidic conditions and said encapsulating resin has been added with an additive forming a compound with a chlorine ion.

27. A semiconductor device, comprising:
a semiconductor element;
a plurality of inner leads made of copper or an alloy thereof and extending around said semiconductor element;
a heat sink which is bonded to one end of each of said plurality of inner leads via an insulating adhesive layer and on which said semiconductor element is to be mounted via said adhesive layer;
a plurality of metal wires each electrically connecting said semiconductor element and each of said plurality of inner leads; and
an encapsulating resin encapsulating therewith said semiconductor element, said plurality of inner leads, said plurality of metal wires, and said heat sink,
wherein a site of said inner lead to be bonded to said adhesive layer is covered with a metal forming a passivation film under acidic conditions, and said encapsulating resin has been added with an ion trapping agent forming a compound with an ionic impurity.

28. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal having a reference electrode potential higher than that of copper, and said encapsulating resin has been added with an additive for controlling the pH of a resin extract available upon a pressure cooker test to 5.5 or greater but not greater than 10.

29. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal having a reference electrode potential higher than that of copper, and said encapsulating resin has been added with an additive forming a compound with a chlorine ion.

30. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal having a reference electrode potential higher than that of copper, and said encapsulating resin has been added with an ion trapping agent forming a compound with an ionic impurity.

31. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal forming a passivation film under acidic conditions and said encapsulating resin has been added with an additive for controlling the pH of a resin extract available upon a pressure cooker test to 5.5 or greater but not greater than 10.

32. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal forming a passivation film under acidic conditions and said encapsulating resin has been added with an additive for forming a compound with a chlorine ion.

33. A semiconductor device, comprising:
a wiring substrate having a plurality of copper foil leads;
a semiconductor element disposed over said wiring substrate;
a plurality of metal wires each electrically connecting said semiconductor element and each of said plurality of copper foil leads;
an encapsulating resin encapsulating therewith said semiconductor element, said plurality of metal wires, and said plurality of copper foil leads; and
a plurality of protruding electrodes disposed on a side of said wiring substrate opposite to the side on which said copper foil leads have been formed,
wherein at least a site of said copper foil leads to be covered with said encapsulating resin is covered with a metal forming a passivation film under acidic conditions and said encapsulating resin has been added with an ion trapping agent forming a compound with an ionic impurity.

34. A semiconductor device, comprising:
a wiring substrate having a plurality of copper foil leads;
a first semiconductor element disposed over said wiring substrate and having, on the main surface of said first semiconductor element, a surface electrode which is exposed from the main surface and a copper interconnect to be connected thereto;
a plurality of protruding electrodes each electrically connecting said first semiconductor element and each of said plurality of copper foil leads of said wiring substrate;
an underfill resin disposed between said wiring substrate and said first semiconductor element and covering said plurality of protruding electrodes;
a second semiconductor element disposed over said wiring substrate;
a plurality of metal wires each electrically connecting said second semiconductor element and said plurality of copper foil leads; and
a potting resin encapsulating therewith said second semiconductor element, said plurality of metal wires, and said plurality of copper foil leads, and having been dropped onto said wiring substrate,
wherein at least one of a resin forming said wiring substrate, a resin protective film covering a portion of said copper foil lead, said underfill resin and said potting resin has been added with an additive for controlling the pH of a resin extract available upon a pressure cooker test to 5.5 or greater but not greater than 10.
